(19) United States
(12) Patent Application Publication
(10) Pub. No.: US 2025/0236775 A1
(43) Pub. Date: Jul. 24, 2025

(54) COMPOSITE STRUCTURE

(71) Applicant: SAMSUNG ELECTRONICS CO., LTD., SUWON-SI (KR)

(72) Inventors: Youngsuk NAM, Daejeon (KR); Jae Choon KIM, Suwon-si (KR); Eunho CHO, Suwon-si (KR); Seokkan KI, Daejeon (KR); Jonggyu LEE, Suwon-si (KR); Seongjong SHIN, Daejeon (KR)

(73) Assignee: Korea Advanced Institute of Science and Technology, Daejeon (KR)

(21) Appl. No.: 18/800,577

(22) Filed: Aug. 12, 2024

(30) Foreign Application Priority Data
Jan. 19, 2024 (KR) 10-2024-0008720

(51) Int. Cl. C09K 5/06

(52) U.S. Cl. CPC C09K 5/06

(57) ABSTRACT

A composite structure includes a substrate including at least one void. A phase-change layer fills at least a portion of the at least one void. An interface layer is between the substrate and the phase-change layer. The substrate includes copper (Cu). The phase-change layer includes gallium (Ga). The interface layer includes a copper gallium (CuGa₂) compound. The interface layer is in direct contact with the substrate and the phase-change layer.

### CROSS-REFERENCE TO RELATED APPLICATIONS

This application claims priority under 35 U.S.C. § 119 to Korean Patent Application No. 10-2024-0008720, filed on Jan. 19, 2024 in the Korean Intellectual Property Office, the disclosure of which is incorporated by reference in its entirety herein.

### 1. TECHNICAL FIELD

The present disclosure relates to a composite structure, and in particular, to a composite structure including a phase-change layer.

### 2. DISCUSSION OF RELATED ART

A phase change material (PCM) is a material having a phase that can be changed from liquid to solid or gas, from solid to liquid or gas, or from gas to liquid or solid. Thus, the phase change material can be used as a latent heat agent, a heat storing agent, a coolant agent, or a thermal-adjusting material. Due to the phase change process, the phase change material can store or exhaust a large amount of heat energy, and it has a high energy storing capacity, compared with typical materials. Therefore, research is being conducted in various fields such as the semiconductor industry, aerospace industry, and food storage industry concerning phase change materials.

### SUMMARY

An embodiment of the present inventive concept provides a composite structure having a phase that can be changed between solid and liquid phases at room temperature.

According to an embodiment of the present inventive concept, a composite structure includes a substrate including at least one void. A phase-change layer fills at least a portion of the at least one void. An interface layer is between the substrate and the phase-change layer. The substrate includes copper (Cu). The phase-change layer includes gallium (Ga). The interface layer includes a copper gallium (CuGa₂) compound. The interface layer is in direct contact with the substrate and the phase-change layer.

According to an embodiment of the present inventive concept, a composite structure includes a substrate including at least one void. A phase-change layer fills at least a portion of the at least one void. An interface layer is between the substrate and the phase-change layer. The substrate comprises copper (Cu). The phase-change layer comprises gallium (Ga). The interface layer comprises a copper gallium (CuGa₂) compound. The interface layer comprises a first layer disposed in the at least one void and a second layer disposed outside of the at least one void. The substrate is disposed between the first layer and the second layer.

According to an embodiment of the present inventive concept, a composite structure includes a substrate including at least one void. A phase-change layer fills at least a portion of the at least one void. An interface layer is in direct contact with the substrate and the phase-change layer. The substrate comprises copper (Cu). The phase-change layer comprises gallium (Ga). The interface layer comprises a copper gallium (CuGa₂) compound. The substrate is spaced apart from the phase-change layer by the interface layer.

### BRIEF DESCRIPTION OF THE DRAWINGS

FIG. 1A is a perspective view schematically illustrating a composite structure according to an embodiment of the present inventive concept.

FIG. 1B is a sectional view taken along a line A-A′ of FIG. 1A according to an embodiment of the present inventive concept.

FIG. 1C is an enlarged view illustrating a portion E of FIG. 1B according to an embodiment of the present inventive concept.

FIG. 2A is a flow chart illustrating a method of manufacturing a composite structure, according to an embodiment of the present inventive concept.

FIGS. 2B, 2C, and 2D are diagrams illustrating a method of manufacturing the composite structure of FIG. 2A according to embodiments of the present inventive concept.

FIG. 3A is a flow chart illustrating a method of experimentally measuring characteristics of a composite structure, according to an embodiment of the present inventive concept.

FIG. 3B is a cross-sectional view illustrating an experiment method of measuring characteristics of the composite structure according to the method of FIG. 3A according to an embodiment of the present inventive concept.

FIGS. 4A and 4B are camera images of a composite structure by the experiment method of FIG. 3A according to embodiments of the present inventive concept.

FIGS. 5A, 5B, 5C, 5D, and 5E are diagrams illustrating characteristics of the composite structures according to the experiment method of FIG. 3A according to embodiments of the present inventive concept.

FIGS. 6A, 6B, 6C, and 6D are diagrams illustrating an experiment method of measuring characteristics of the composite structure, according to some embodiments of the present inventive concept.

### DETAILED DESCRIPTION OF EMBODIMENTS

Example embodiments of the present inventive concept will now be described more fully with reference to the accompanying drawings, in which example embodiments are shown.

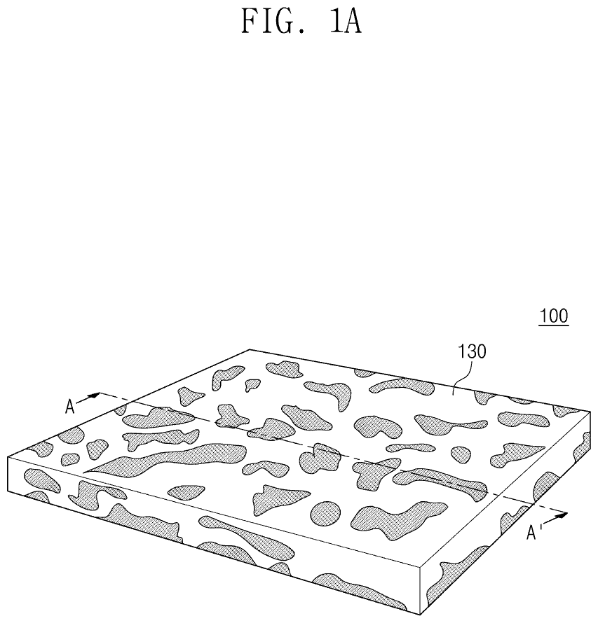

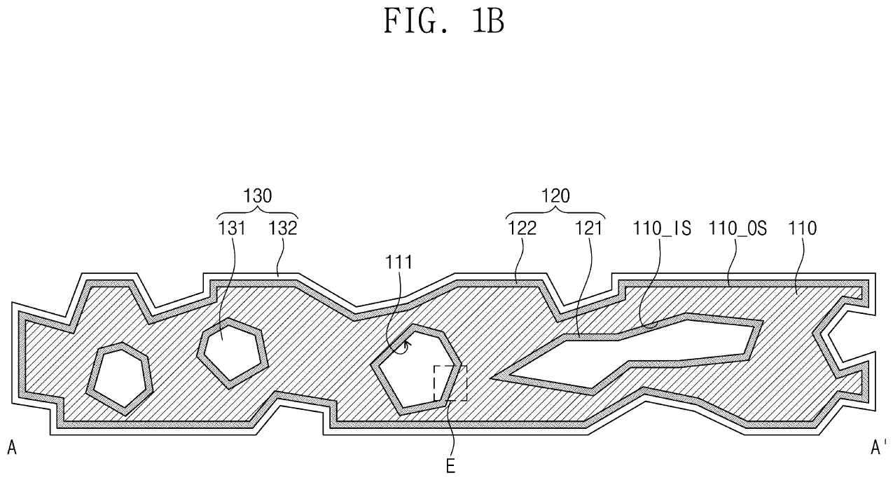

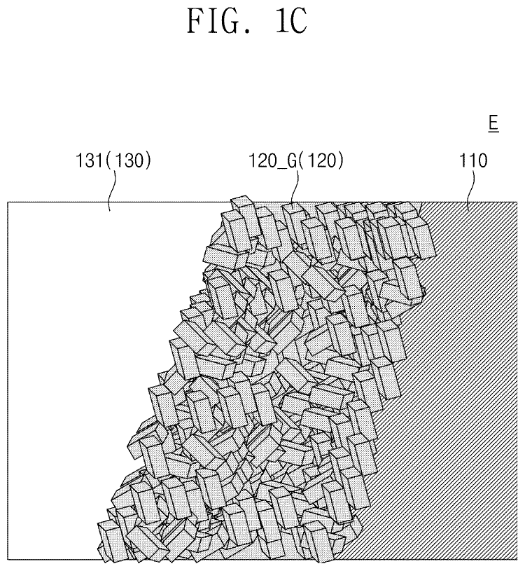

FIG. 1A is a perspective view schematically illustrating a composite structure according to an embodiment of the present inventive concept. FIG. 1B is a cross-sectional view taken along a line A-A′ of FIG. 1A. FIG. 1C is an enlarged view illustrating a portion E of FIG. 1B.

Referring to FIGS. 1A and 1B, a composite structure 100 may be provided. In an embodiment, the composite structure 100 may include a substrate 110, an interface layer 120, and a phase-change layer 130. The interface layer 120 may be provided to enclose the entire surface of the substrate 110. For example, the substrate 110 may be enclosed by the interface layer 120 and may not be exposed to the outside (e.g., the external environment). The substrate 110 may be spaced apart from the phase-change layer 130 by the interface layer 120. In an embodiment, the phase-change layer 130 may enclose all surfaces of the interface layer 120. The interface layer 120 may be enclosed by the phase-change layer 130 and may not be exposed to the outside (e.g., the external environment). The interface layer 120 may be disposed between the substrate 110 and the phase-change layer 130. In an embodiment, the interface layer 120 may be in direct contact with the substrate 110 and the phase-change layer 130. In an embodiment, the substrate 110 may be closed by the phase-change layer 130 and the interface layer 120.

In an embodiment, the substrate 110 may be a porous foam with at least one void 111. For example, in an embodiment the substrate 110 may have a pore density ranging in a range from about 20 ppi (pore per inch) to about 80 ppi. For example, in an embodiment the substrate 110 may have a pore density of about 50 ppi. In an embodiment, the substrate 110 may have a pore density of about 80 ppi. The substrate 110 may include a metallic material. In an embodiment, the substrate 110 may be formed of or include copper (Cu).

Due to the presence of the void 111, the substrate 110 may have a structure having an inner space that is opened. The void 111 may be an empty space that is formed to open the inner space of the substrate 110. In an embodiment, the porosity of the substrate 110 may be about 0.9. For example, 90% of a total volume of the substrate 110 may be an empty space. In an embodiment, the void 111 may include a plurality of voids, and the inner space of the substrate 110 may be opened by the voids.

The interface layer 120 may be disposed between the substrate 110 and the phase-change layer 130. The interface layer 120 may be in direct contact with the substrate 110 and the phase-change layer 130. In an embodiment, the interface layer 120 may include an intermetallic compound (IMC) between the substrate 110 and the phase-change layer 130. As an example, the interface layer 120 may include a copper gallium (CuGa₂) compound.

The phase-change layer 130 may include a phase change material (PCM). The phase change material (PCM) of the phase-change layer 130 may be a metallic material in which the phase is changed from solid to liquid at the room temperature. As an example, in an embodiment the phase-change layer 130 may include gallium (Ga). When a phase of the phase-change layer 130 is changed from liquid to solid, a nucleation process may begin on a surface in direct contact with the interface layer 120. When a phase of the phase-change layer 130 is changed from liquid to solid, the nucleation process may begin at the room temperature. In an embodiment, when a phase of the phase-change layer 130 is changed from liquid to solid, the nucleation process may begin at a temperature between about 5° C. to about 29.8° C.

The substrate 110 may include an inner surface 110_IS and an outer surface 110_OS. The inner surface 110_IS of the substrate 110 may define the at least one void 111. The outer surface 110_OS may be a surface of the substrate 110 positioned outside the void 111.

In an embodiment, the interface layer 120 may include a first layer 121 and a second layer 122. The first layer 121 of the interface layer 120 may cover the inner surface 110_IS of the substrate 110. The first layer 121 of the interface layer 120 may be in direct contact with the inner surface 110_IS of the substrate 110. The first layer 121 of the interface layer 120 may fill at least a portion of the at least one void 111. The second layer 122 may cover the outer surface 110_OS of the substrate 110. The second layer 122 may be in direct contact with the outer surface 110_OS of the substrate 110. The substrate 110 may be disposed between the first and second layers 121 and 122 of the interface layer 120. In an embodiment, the first and second layers 121 and 122 of the interface layer 120 may be connected to form a single object. Thus, the substrate 110 may be closed by the interface layer 120.

In an embodiment, the phase-change layer 130 may include a first portion 131 and a second portion 132. The first portion 131 of the phase-change layer 130 may be disposed in the void 111 of the substrate 110. The second portion 132 of the phase-change layer 130 may be spaced apart from the outside of the at least one void 111 of the substrate 110 and may cover the second layer 122 of the interface layer. For example, in an embodiment the second portion 132 of the phase-change layer 130 may be spaced apart from the at least one void 111 by the first layer 121 of the interface layer, the substrate 110 and the second layer 122 of the interface layer.

The first portion 131 of the phase-change layer 130 may be in direct contact with the first layer 121 of the interface layer 120 (e.g., an inner surface of the first layer 121). The first portion 131 of the phase-change layer 130 may fill at least a portion of the void 111 of the substrate 110. In an embodiment, the void 111 of the substrate 110 may be fully filled with the first portion 131 of the phase-change layer 130 and the first layer 121 of the interface layer 120. In an embodiment, the entirety of the void 111 of the substrate 110 may not be filled with the first portion 131 of the phase-change layer 130 and the first layer 121 of the interface layer 120. In this embodiment, the void 111 of the substrate 110 may include an empty space that is defined by the first portion 131 of the phase-change layer 130.

The second portion 132 of the phase-change layer 130 may be in direct contact with the second layer 122 of the interface layer 120 (e.g., an outer surface of the second layer 122). In an embodiment, the second portion 132 of the phase-change layer 130 may be provided to fully cover the second layer 122 of the interface layer 120. For example, the second portion 132 of the phase-change layer 130 may surround the entire surface of the interface layer 120, such as the entire surface of the second layer 122 of the interface layer 120.

The substrate 110 and the interface layer 120 may be disposed between the first and second portions 131 and 132 of the phase-change layer 130. In some embodiments, the first and second portions 131 and 132 of the phase-change layer 130 may be connected to form a single object. Thus, the interface layer 120 may be closed by the phase-change layer 130.

The first layer 121 of the interface layer 120 may be disposed between the inner surface 110_IS of the substrate 110 and the first portion 131 of the phase-change layer 130 (e.g., an outer surface of the first portion 131). The inner surface 110_IS of the substrate 110 and the first portion 131 of the phase-change layer 130 may be spaced apart from each other by the first layer 121 of the interface layer 120. The second layer 122 of the interface layer 120 may be disposed between the outer surface 110_OS of the substrate 110 and the second portion 132 of the phase-change layer 130 (e.g., an inner surface of the second portion 132). The outer surface 110_OS of the substrate 110 and the second portion 132 of the phase-change layer 130 may be spaced apart from each other by the second layer 122 of the interface layer 120, such as the second layer 122 of the interface layer.

In an embodiment, a thickness of the first layer 121 of the interface layer 120 may be less than a width (e.g., a width in the horizontal direction) of the first portion 131 of the phase-change layer 130. A thickness of the second layer 122 of the interface layer 120 may be less than a thickness of the second portion 132 of the phase-change layer 130.

Referring to FIG. 1C, in an embodiment the interface layer 120 may have a polycrystalline structure including a plurality of grains 120_G. The grains 120_G of the interface layer 120 may include a first side, a second side, and a third side, which are connected to each other. The first to third sides may cross each other. For example, in an embodiment the first to third sides may be orthogonal to each other. In an embodiment, a length of the third side of the grain 120_G may be greater than a length of the first side and a length of the second side. In an embodiment, the grain 120_G may have a cuboidal shape.

According to an embodiment of the present inventive concept, the composite structure 100 may include the phase-change layer 130 having a phase that can be changed from solid to liquid at the room temperature. Thus, the phase-change layer 130 may absorb heat from neighboring elements, during the phase-changing process, and in this embodiment, the phase-change layer 130 may reduce a heating issue in an electronic device with the composite structure 100.

In an embodiment, the composite structure 100 may include the interface layer 120 between the substrate 110 and the phase-change layer 130, and the interface layer 120 may be configured to expedite the nucleation process during the phase-changing process of the phase-change layer 130. Due to the interface layer 120, the phase of the phase-change layer 130 may be changed from liquid to solid at the room temperature, and in this embodiment, a supercooling issue may be alleviated. Thus, the phase of the phase-change layer 130 may be restored to the solid phase at the room temperature.

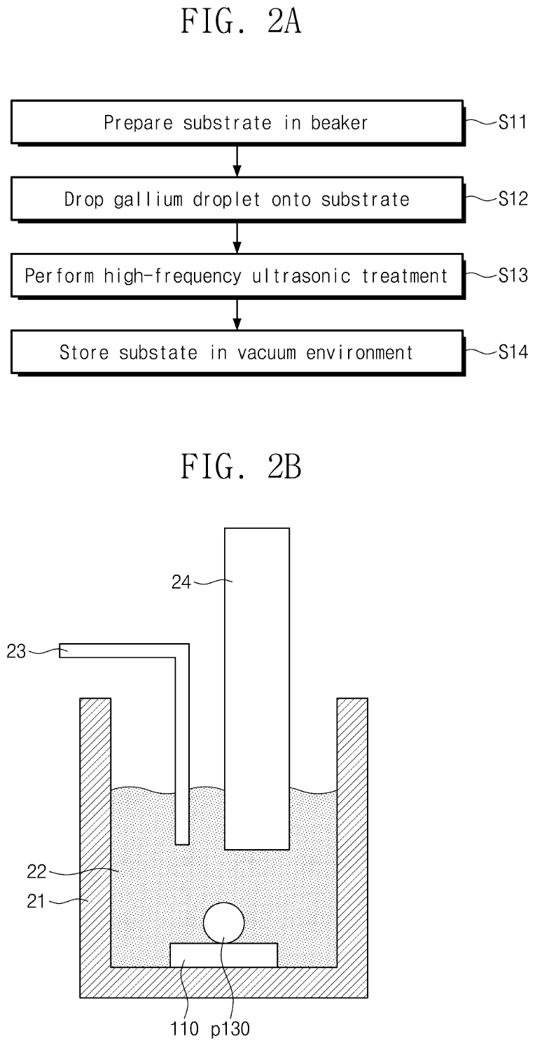

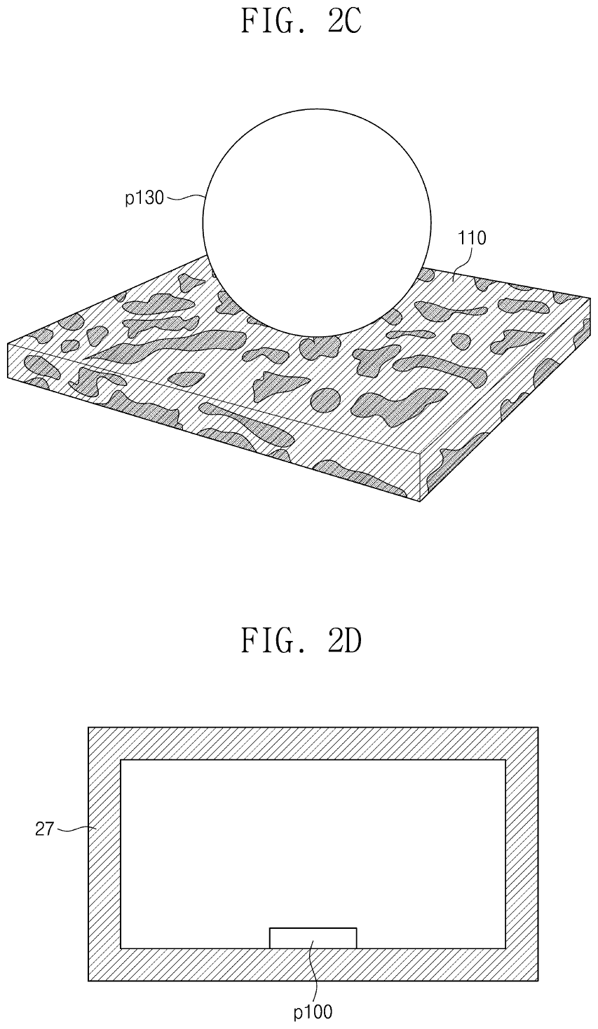

FIG. 2A is a flow chart illustrating a method of manufacturing a composite structure, according to an embodiment of the present inventive concept. FIGS. 2B, 2C, and 2D are diagrams illustrating a method of manufacturing the composite structure of FIG. 2A.

Referring to FIG. 2A, in an embodiment the method of manufacturing the composite structure may include preparing a substrate in a beaker in block S11, dropping a gallium droplet onto the substrate in block S12, performing a high-frequency ultrasonic treatment in block S13, and storing the treated substate in a vacuum environment in block S14.

Referring to FIGS. 2B, 2C, and 2D, in an embodiment a substrate 110 and acidic aqueous solution 22 may be provided in a beaker 21 in block S11. The substrate 110 may be immersed in the acidic aqueous solution 22. In an embodiment, the beaker 21 may be a double-wall beaker including a constant temperature water tank. An internal temperature of the beaker 21 may be maintained to about 30° C. or higher by the constant temperature water tank of the beaker 21. For example, the internal temperature of the beaker 21 may be maintained to about 35° C. Thus, a gallium droplet p130, which will be described below, may be prevented from being changed to a solid phase and to maintain the gallium droplet p130 in a liquid phase. In an embodiment, the acidic aqueous solution 22 may include hydrochloric acid (HCl). As an example, the acidic aqueous solution 22 may be 3M hydrochloric acid (HCl). The acidic aqueous solution 22 may be used to dissolve an oxide material, which is formed on the surface of the substrate 110, and an oxide material, which is formed on the surface of the gallium droplet p130. Accordingly, the substrate 110 and the gallium droplet p130, which are dipped in the acidic aqueous solution 22, may not include an oxide material.

In an embodiment, a pump 23 and a sonicator 24 may be provided near the beaker 21. In an embodiment, the pump 23 may be used to drop the gallium droplet p130 onto the substrate 110 in block S12 (e.g., directly on the substrate 110). Due to the surface tension of the gallium droplet p130, the gallium droplet p130 may not fill an inner space of the substrate 110. The gallium droplet p130 on the substrate 110 may be present in the form of a water drop. As an example, the surface tension of the gallium droplet p130 may be about 708 mN/m.

In an embodiment, the sonicator 24 may be used to perform a high-frequency ultrasonic treatment on the substrate 110 and the gallium droplet p130 in block S13. The composite structure 100 may be formed by the high-frequency ultrasonic treatment. In an embodiment, the sonicator 24 may generate an ultrasonic wave of about 20 KHZ. The gallium droplet p130 may be vibrated by the ultrasonic wave. Since the gallium droplet p130 is vibrated, a surface area of the substrate 110 in direct contact with the gallium droplet p130 may be increased. An intermetallic compound, which is used as the interface layer 120 of FIG. 1B, may be formed in a region where the gallium droplet p130 and the substrate 110 are in direct contact with each other. Due to the formation of the interface layer 120, the inner space of the substrate 110 may be filled with the gallium droplet p130. In addition, the gallium droplet p130 may not only fill an inner space of the substrate 110 but also cover the entire surface of the substrate 110. The gallium droplet p130 filling the substrate 110 and covering the entire surface of the substrate 110 may be defined as the phase-change layer 130 of the composite structure 100. In an embodiment, the high-frequency ultrasonic treatment through the sonicator 24 may be performed in a range of about 15 to about 20 minutes.

The composite structure 100 may be transferred in a desicator 27 and may be stored in a vacuum environment in block S14. The desicator 27 may be in a vacuum state. In an embodiment, before the storing of the composite structure 100 in the vacuum environment, the composite structure 100 may include air pores which are present between the substrate 110, the interface layer 120, and the phase-change layer 130. Since the composite structure 100 is stored in the vacuum environment of the desicator 27, the air pore may be fully removed from the composite structure 100.

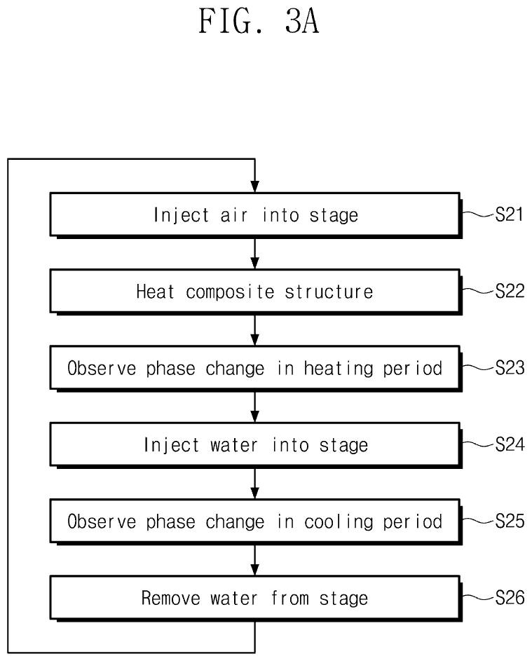

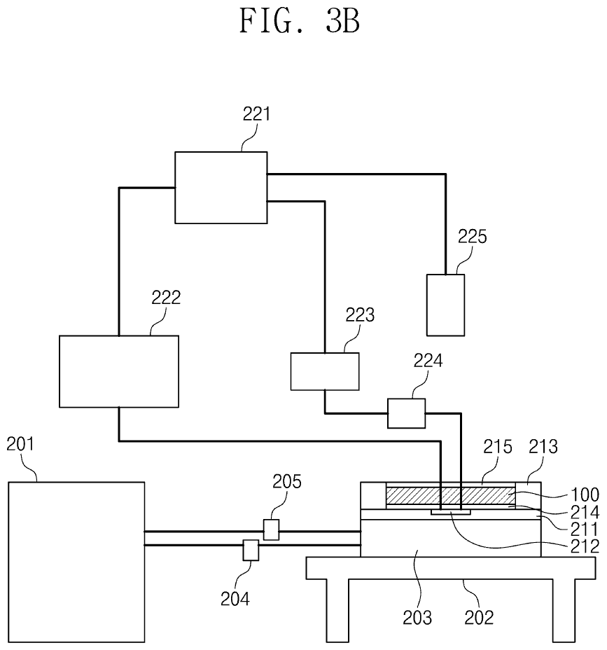

FIG. 3A is a flow chart illustrating a method of experimentally measuring characteristics of a composite structure, according to an embodiment of the present inventive concept. FIG. 3B is a cross-sectional view illustrating an experiment method of measuring characteristics of the composite structure according to the method of FIG. 3A.

Referring to FIG. 3A, in an embodiment the measurement may include injecting the air into a stage in block S21, heating a composite structure in block S22, observing a phase change in a heating period in block S23, injecting water into the stage in block S24, observing a phase change in a cooling period in block S25, and removing the water from the stage in block S26.

Referring to FIG. 3B, a water tank 201, an anti-vibration device 202, and a stage 203 may be provided. The stage 203 may be placed on (e.g., disposed directly thereon) the anti-vibration device 202. The anti-vibration device 202 may be used to absorb an external impact applied during the experiment process. In the cooling experiment, the water may be supplied into the stage 203, and in the heating experiment, the air may be supplied into the stage 203. The water tank 201 may be connected to the stage 203. The water tank 201 may include the water that is maintained at a constant temperature. In an embodiment, the water tank 201 may be configured to supply the water into the stage 203 or to receive the water from the stage 203. In the cooling experiment, the water may be supplied from the water tank 201 to the stage 203. In the heating experiment, the water may be moved from the stage 203 to the water tank 201, and in this case, only the air may exist in the stage 203.

A valve 204 and a flow meter 205 may be further provided between the water tank 201 and the stage 203. In the heating experiment, the valve 204 may be opened to inject the air into the stage 203. In the cooling experiment, the valve 204 may be closed to supply the water from the water tank 201 to the stage 203. The flow of the water between the water tank 201 and the stage 203 may be adjusted by the flow meter 205.

In an embodiment, a substrate 211, a heating chip 212, a fastening device 213, a first protection layer 214, a second protection layer 215, and the composite structure 100 may be provided. The composite structure 100 may be the composite structure 100 of FIGS. 1A to 1C.

The substrate 211 may be provided on (e.g., placed directly thereon) the stage 203. The substrate 211 may include a metallic material. As an example, in an embodiment the substrate 211 may include copper (Cu). Since the substrate 211 includes a metallic material, heat, which is generated from the heating chip 212, may be transferred to the composite structure 100.

The heating chip 212 may be provided in the substrate 211. In an embodiment, the heating chip 212 may be provided to the outside of the substrate 211 through a top surface of the substrate 211. The heating chip 212 may include a micro heater. Thus, a current supplied from the outside (e.g., the external environment) may be used to generate heat in the heating chip 212. In an embodiment, the heating chip 212 may include a thermometer.

The fastening device 213 may be provided on the top surface of the substrate 211 and a side surface of the composite structure 100. The fastening device 213 may be placed to enclose the side surface of the composite structure 100. The fastening device 213 may be used to fasten the composite structure 100. Thus, it may be possible to relieve an external impact applied during the experiment process. The fastening device 213 may include a heat-resistant material. In an embodiment, the fastening device 213 may include polycarbonate.

In an embodiment, the first protection layer 214 may be provided between (e.g., directly therebetween) the substrate 211 and the composite structure 100, and the second protection layer 215 may be provided on (e.g., directly thereon) a top surface of the composite structure 100. The first protection layer 214 may be disposed between (e.g., directly therebetween) the top surface of the substrate 211 and the bottom surface of the composite structure 100. The first protection layer 214 may be in direct contact with the top surface of the substrate 211, the top surface of the heating chip 212, and the bottom surface of the composite structure 100. The first protection layer 214 may separate the heating chip 212 from the composite structure 100. Thus, an occurrence of a short circuit may be prevented in the heating chip 212.

In an embodiment, the second protection layer 215 may be in direct contact with the top surface of the substrate 211 and the fastening device 213. A side surface (e.g., lateral side surfaces) of the second protection layer 215 may be enclosed by the fastening device 213. The second protection layer 215, along with the fastening device 213, may be configured to fasten the composite structure 100.

In an embodiment, the first protection layer 214 and the second protection layer 215 may include a polymer insulating material. The first protection layer 214 and the second protection layer 215 may include a transparent material. The composite structure 100 may be observed through the transparent second protection layer 215. In an embodiment, the first protection layer 214 and the second protection layer 215 may include polydimethylsiloxane (PDMS).

In an embodiment, a computer 221, a power unit 222, a data gathering device 223, a temperature measuring sensor 224, and a camera 225 may be provided. The computer 221 may be connected to the power unit 222, the data gathering device 223, the temperature measuring sensor 224, and the camera 225 and may be used to control them. In an embodiment, the computer 221 may be used to write or store data, which are obtained from the data gathering device 223, the temperature measuring sensor 224, and the camera 225.

The power unit 222 may be connected to the heating chip 212. The power unit 222 may be configured to supply an electric power to the heating chip 212. In an embodiment, by adjusting a voltage of the power unit 222 using the computer 221, an electric power that is supplied to the heating chip 212 may be controlled. By adjusting the electric power that is supplied to the heating chip 212 using the computer 221, a flux of heat generated in the heating chip 212 may be controlled.

The data gathering device 223 and the temperature measuring sensor 224 may be connected to the heating chip 212. The temperature measuring sensor 224 may be connected to the thermometer of the heating chip 212. The temperature measuring sensor 224 may be connected to the thermometer of the heating chip 212 to measure a temperature of the composite structure 100. In an embodiment, temperature data of the composite structure 100, which is measured through the temperature measuring sensor 224, may be gathered by the data gathering device 223. The temperature data of the composite structure 100 that is gathered by the data gathering device 223 may be stored in the computer 221.

In an embodiment, the camera 225 may be vertically spaced apart from the composite structure 100 by a specific distance. For example, the camera 225 may be provided to be overlapped with the composite structure 100 (e.g., in the vertical direction). The camera 225 may be positioned to obtain an image of the composite structure 100 therebelow. When the composite structure 100 is heated or cooled, the image of the composite structure 100 may be obtained by the camera 225. In an embodiment, the image of the composite structure 100, which is obtained by the camera 225, may be stored in the computer 221.

Referring back to FIGS. 3A and 3B, for the heating experiment, the valve 204 may be opened to inject the air into the stage 203 in block S21. As a current is supplied to the heating chip 212 through the power unit 222, heat may be generated in the heating chip 212. The composite structure 100 may be heated by the heat which is generated in the heating chip 212 in block S22. For example, the heating chip 212 may heat the composite structure 100 in a power density of about 40 W/cm² for about 1 minute. The phase change of the phase-change layer 130 may be observed, during heating the composite structure 100 using the camera 225 in block S23.

For the cooling experiment, the valve 204 may be closed to inject the water of the water tank 201 into the stage 203 in block S24. In an embodiment, the water, which is injected into the stage 203, may be used to cool the composite structure 100 for about 5 minutes. In an embodiment, the temperature of the water may be about 20° C. The phase change of the phase-change layer 130 may be observed, during cooling the composite structure 100 using the camera 225 in block S25.

For a next heating experiment, the water of the stage 203 may be moved to the water tank 201 and may be removed from the stage 203 in block S26. The valve 204 may be opened to inject the air into the stage 203 in block S21, and then, the heating experiment may be performed again in block S22. The heating experiment and the cooling experiment may be repeated several times.

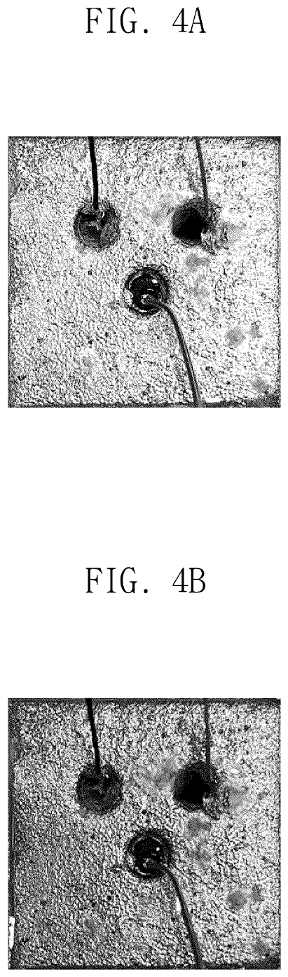

FIGS. 4A and 4B are camera images of a composite structure by the experiment method of FIG. 3A.

Referring to FIG. 4A, the phase-change layer 130 of the composite structure 100 was liquefied as a result of the heating of the composite structure 100 in the heating experiment. During the heating experiment, the phase of the phase-change layer 130 of the composite structure 100 was changed from solid to liquid.

Referring to FIG. 4B, the phase-change layer 130 of the composite structure 100 was solidified as a result of the cooling of the composite structure 100 in the cooling experiment. During the cooling experiment, the phase of the phase-change layer 130 of the composite structure 100 was changed from liquid to solid.

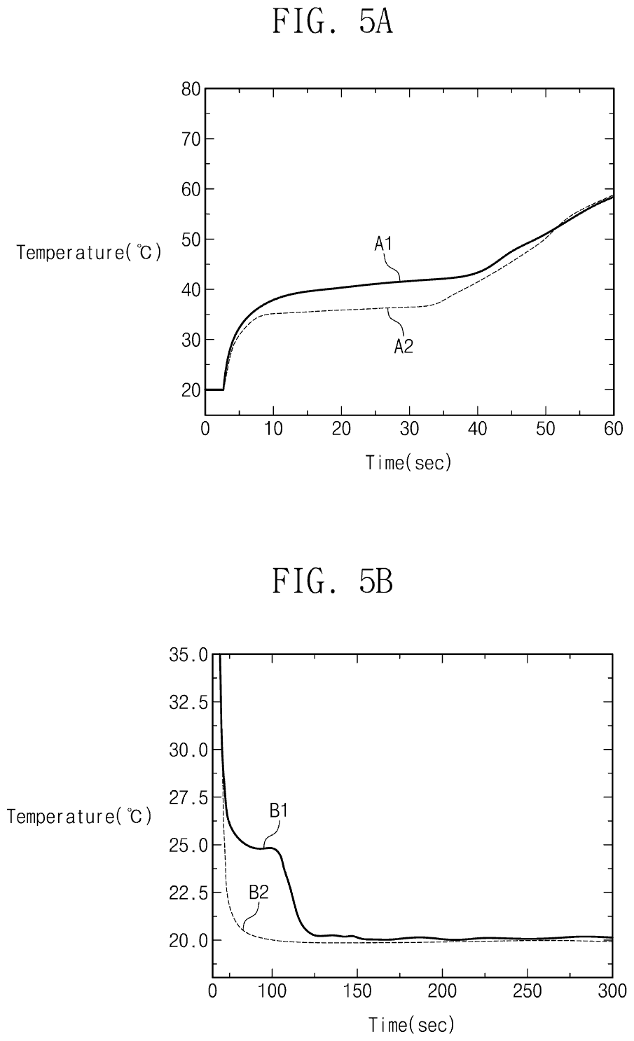

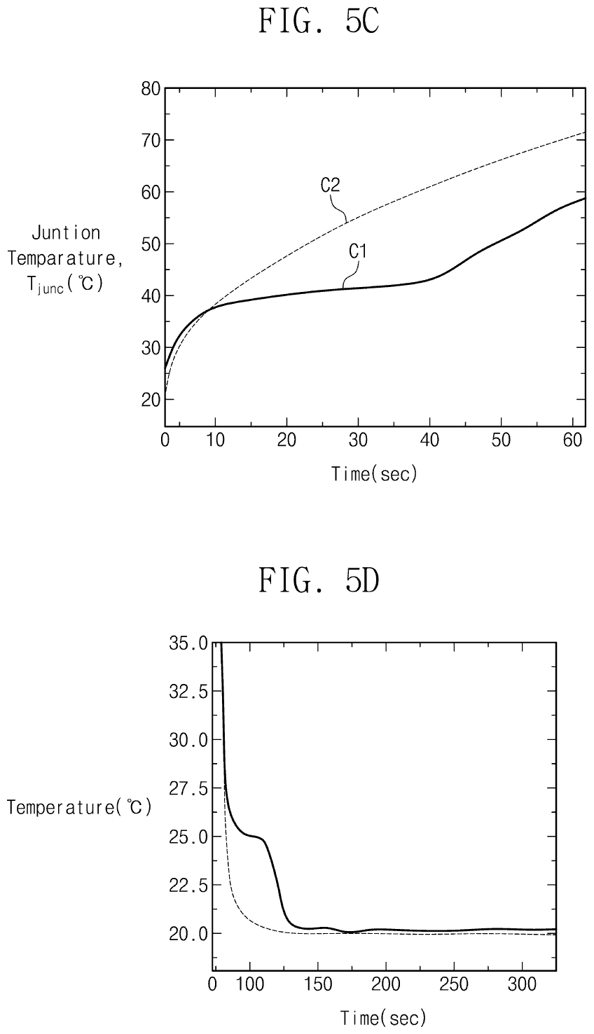

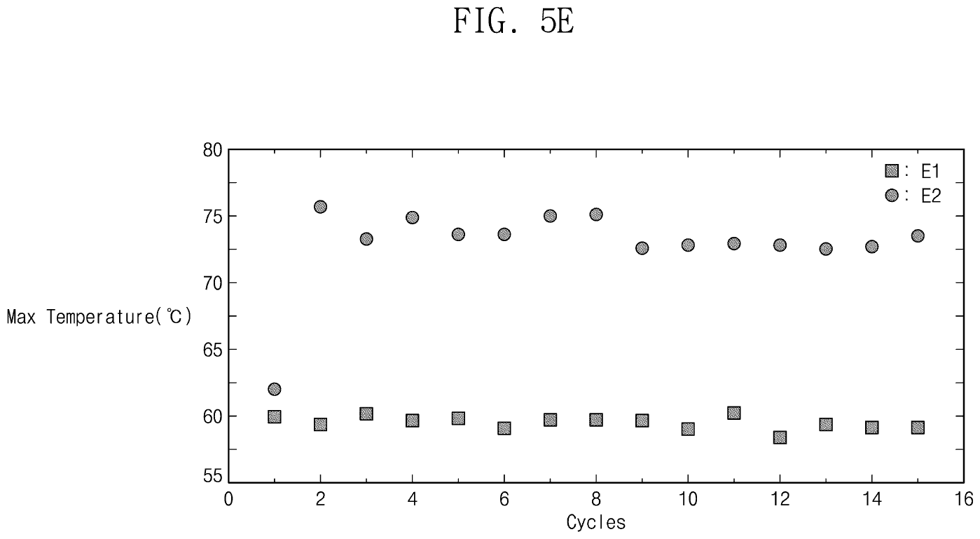

FIGS. 5A, 5B, 5C, 5D, and 5E are graphs illustrating characteristics of composite structures according to the experiment method of FIG. 3A. The composite structure 100 may be the composite structure 100 of FIGS. 1A to 1C.

FIG. 5A illustrates a temperature change A1 of the composite structure 100 in the 1^{st} cycle heating experiment which is represented by a solid line and a temperature change A2 of the gallium sample in the 1^{st} cycle heating experiment which is represented by a dotted line. The composite structure 100 and the gallium sample were disposed on the stage 203, and the 1^{st} cycle heating experiment was performed thereon. The gallium sample did not include a void, unlike the composite structure 100. In an embodiment, the gallium sample was pure gallium. All of the phase-change layer 130 of the composite structure 100 and the gallium sample were in a solid state before the 1^{st} cycle heating experiment was conducted. As a result of the heating experiment, all of the phase-change layer 130 of the composite structure 100 and the gallium sample were changed from solid to liquid at a temperature of 30 to 40° C. The phase-change layer 130 of the composite structure 100 and the gallium sample absorbed heat in the form of latent heat in the time period of 10 seconds to 40 seconds, and thus, the increase of temperature was delayed, as shown in FIG. 5A.

FIG. 5B illustrates a temperature change B1 of the composite structure 100 in the 1^{st} cycle cooling experiment which is represented by a solid line and a temperature change B2 of a gallium sample in the 1^{st} cycle cooling experiment which is represented by a dotted line, after the 1^{st} cycle heating experiment. All of the phase-change layer 130 of the composite structure 100 and the gallium sample before the 1^{st} cycle cooling experiment was conducted were in a liquid state. The composite structure 100 and the gallium sample were disposed on the stage 203, and the 1^{st} cycle cooling experiment was performed thereon. In the 1^{st} cycle cooling experiment, the composite structure 100 and the gallium sample were cooled to 20° C. Due to a supercooling phenomenon, the phase of the gallium sample was not changed from liquid to solid in the cooling experiment. In addition, heating by the latent heat did not occur in the gallium sample, and the temperature was abruptly lowered. In contrast, the phase of the phase-change layer 130 of the composite structure 100 was quickly changed from liquid to solid immediately after the cooling step. Furthermore, in the time period from the start of the cooling step to 100 seconds, the temperature lowering of the phase-change layer 130 of the composite structure 100 was delayed due to heat release by latent heat.

FIG. 5C illustrates a temperature change C1 of the composite structure 100 in the 2^{nd} cycle heating experiment which is represented by a solid line and a temperature change C2 of the gallium sample in the 2^{nd} cycle heating experiment which is represented by a dotted line, after the 1^{st} cycle cooling experiment. Before the 2^{nd} cycle heating experiment was conducted, the composite structure 100 was in a solid state, and the gallium sample was in a liquid state. The phase of the gallium sample was not changed to solid by the 1^{st} cycle cooling experiment and was in the liquid state after the 1^{st} cycle cooling experiment was completed. The composite structure 100 and the gallium sample were disposed on the stage 203, and the 2^{nd} cycle heating experiment was performed thereon.

In the 2^{nd} cycle heating experiment, the gallium sample and the composite structure 100 were heated for 1 minute in a power density of 40 W/cm². The gallium sample in a liquid state absorbed only the heat in the form of sensible heat, not in the form of latent heat. Thus, since heat applied to the gallium sample was used to change only the temperature of the gallium sample, the temperature of the gallium sample was abruptly increased during the heating experiment for 1 minute. In contrast, the phase of the phase-change layer 130 of the composite structure 100 was changed from solid to liquid at a temperature of 30° C. to 40° C. In addition, the composite structure 100 absorbed heat, which was provided in the form of latent heat, in the time period of 10 seconds to 40 seconds, and thus, the increase of temperature was delayed.

FIG. 5D illustrates a temperature change D1 of the composite structure 100 in the 2^{nd} cycle cooling experiment which is represented by a solid line and a temperature change D2 of the gallium sample in the 2^{nd} cycle cooling experiment, after the 2^{nd} cycle heating experiment was conducted which is represented by a dotted line. All of the phase-change layer 130 of the composite structure 100 and the gallium sample were in a liquid state, before the 2^{nd} cycle cooling experiment was conducted. The composite structure 100 and the gallium sample were disposed on the stage 203, and the 2^{nd} cycle cooling experiment was performed thereon. In the 2^{nd} cycle cooling experiment, the composite structure 100 and the gallium sample were cooled to 20° C. The result of the 2^{nd} cycle cooling experiment was similar to the result of the 1^{st} cycle cooling experiment. Owing to the supercooling phenomenon, the phase of the gallium sample was not changed from liquid to solid, similar to the 1^{st} cycle cooling experiment. In contrast, the phase of the phase-change layer 130 of the composite structure 100 was changed from liquid to solid, and the decrease of temperature was delayed, similar to the 1^{st} cycle cooling experiment.

FIG. 5E illustrates the highest temperature E1 of the composite structure 100 represented by square graph points and the highest temperature E2 of the gallium sample in the 1^{st} to 15^{th} cycle heating experiments represented by circular graph points. The heating experiment and the cooling experiment were repeated in the 1^{st} to 15^{th} cycles, and the highest temperatures of the composite structure 100 and the gallium sample in the 1^{st} to 15^{th} cycle heating experiments were measured.

The highest temperature of the gallium sample was 70° C. or higher in the heating experiments of all cycles excluding the 1^{st} cycle. In addition, the phase of the gallium sample was not changed from liquid to solid in the cooling experiment, which was performed before the heating experiment. This shows that the gallium sample did not overcome a supercooling issue in the cooling experiment and was not restored to the solid phase. Since the gallium sample was maintained to the liquid phase, the gallium sample in the heating experiment absorbed only the sensible heat and had a temperature of 70° C. or higher.

In all cycles of the heating experiments, the highest temperature of the composite structure 100 was less than or equal to 60° C. In addition, the phase of the phase-change layer 130 of the composite structure 100 was restored from liquid to solid phase in the cooling experiment before the heating experiment. This shows that the phase-change layer 130 of the composite structure 100 contributed to overcoming a supercooling issue in the cooling experiment and was restored to the solid phase. Since the phase-change layer 130 of the composite structure 100 was restored to the solid phase, the phase-change layer 130 of the composite structure 100 in the heating experiment absorbed heat in the form of latent heat to delay an increase of temperature, and as a result, the highest temperature was lower than or equal to 60° C.

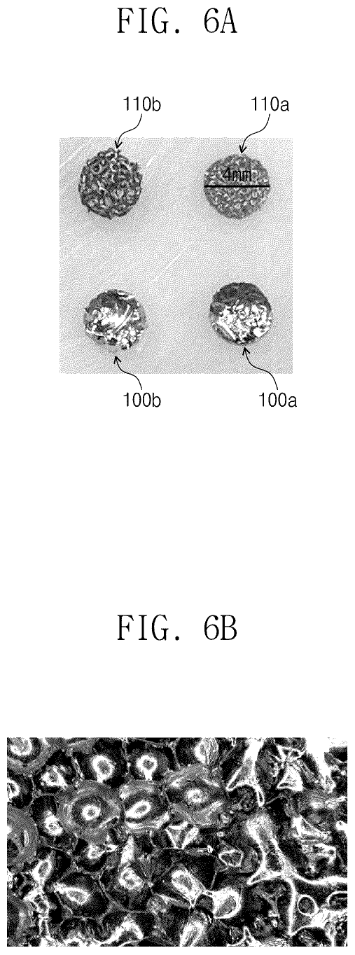

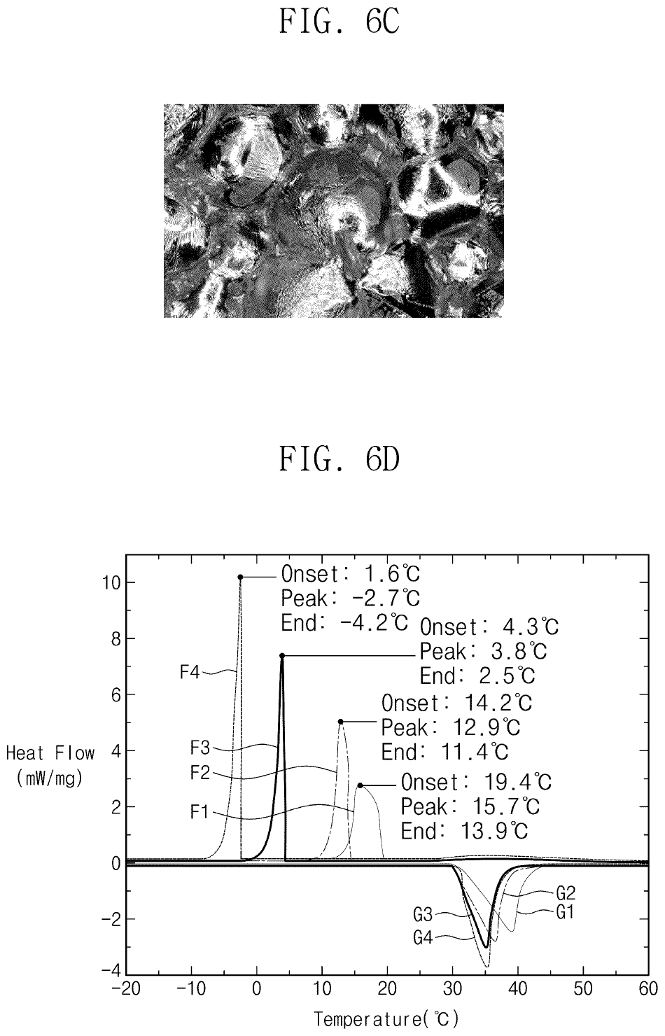

FIGS. 6A, 6B, 6C, and 6D are diagrams illustrating an experiment method of measuring characteristics of the composite structure, according to some embodiments of the present inventive concept. The composite structure 100 may be the composite structure 100 of FIGS. 1A to 1C.

Referring to FIGS. 6A to 6D, a differential scanning calorimetry (DSC) experiment was performed on a first sample, a second sample, a third sample, and a fourth sample. The first sample was the composite structure 100, in which the substrate 110 had a void density of 70 ppi. The second sample was the composite structure 100, in which the substrate 110 had a void density of 50 ppi. The third sample was the composite structure 100, in which the substrate 110 had a void density of 20 ppi. The fourth sample was pure gallium (Ga) without a porous substrate. Each of the first to fourth samples had a mass of 10 mg or greater. Each of the first to fourth samples had a diameter of 4 mm or smaller. Each of the first to fourth samples had a height of 2 mm or smaller.

Referring to FIG. 6A, a first sample 100a and a second sample 100b were prepared. The first sample 100a was formed from the substrate 110a having a pore density of 70 ppi. The second sample 100b was formed from the substrate 110b having a pore density of 50 ppi. The third sample was formed from the substrate 110 having a pore density of 20 ppi. The fourth sample did not include the substrate 110.

FIG. 6B is a scanning electron microscope (SEM) image of the first sample 100a of FIG. 6A. FIG. 6C is a SEM image of the second sample 100b of FIG. 6A. Referring to FIGS. 6B and 6C, since the pore density of the first sample 100a was greater than the pore density of the second sample 100b, a width of a void in the first sample 100a was less than a width of a void in the second sample 100b. This means that an area of the interface layer 120 filling the void was greater in the first sample 100a than in the second sample 100b, and an area of the phase-change layer 130 in direct contact with the interface layer 120 was greater in the first sample 100a than in the second sample 100b.

FIG. 6D is a graph showing a result of a differential scanning calorimetry (DSC) experiment performed on the first to fourth samples with different pore densities. FIG. 6D illustrates a thermal emission change F1 in the cooling experiment on the first sample, a thermal emission change F2 in the cooling experiment on the second sample, a thermal emission change F3 in the cooling experiment on the third sample, a thermal emission change F4 in the cooling experiment on the fourth sample, a thermal absorption change G1 in the heating experiment on the first sample, a thermal absorption change G2 in the heating experiment on the second sample, a thermal absorption change G3 in the heating experiment on the third sample, and a thermal absorption change G4 in the heating experiment on the fourth sample.

Each of the cooling experiments F1, F2, F3, and F4 on the first to fourth samples was performed while lowering the ambient temperature from 60° C. to −20° C. In each of the first to fourth samples, the increase of heat flow began at an Onset temperature. For example, in each of the first to fourth samples, the heat emission began at the Onset temperature. In each of the first to fourth samples, the heat flow was maximized at a Peak temperature. For example, in each of the first to fourth samples, the heat emission was maximized at the Peak temperature. In each of the first to fourth samples, the heat flow vanished at an End temperature. For example, in each of the first to fourth samples, the heat emission was finished at the End temperature.

For the first sample, the phase change to the solid phase started at 19.4° C. (Onset), the phase change maximized at 12.9° C. (Peak), and the phase change to the solid phase finished at 13.9° C. (End). For the second sample, the phase change to the solid phase started at 14.2° C. (Onset), the phase change maximized at 12.9° C. (Peak), and the phase change to the solid phase finished at 11.4° C. (End). For the third sample, the phase change to the solid phase started at 4.3° C. (Onset), the phase change maximized at 2.8° C. (Peak), and the phase change to the solid phase finished at 2.5° C. (End). For the fourth sample, the phase change to the solid phase started at 1.6° C. (Onset), the phase change maximized at −2.7° C. (Peak), and the phase change to the solid phase finished at −4.2° C. (End).

According to the cooling experiments F1, F2, F3, and F4 on the first to fourth samples, the greater the pore density of the substrate 110 of the composite structure 100, the greater the temperature, at which the phase change from the liquid phase to the solid phase occurred. This shows that as the pore density of the substrate 110 of the composite structure 100 increases, the phase change begins at a temperature close to 19.4° C., the melting point of gallium. This shows that the greater the pore density of the substrate 110 of the composite structure 100, the greater the ability of suppressing the supercooling issue.

Each of the heating experiments G1, G2, G3, and G4 of the first to fourth samples was performed while increasing the temperature from −20° C. to 60° C. For each of the first to fourth samples, the reduction of heat flow began at 19.4° C., the melting point of gallium. For example, for each of the first to fourth samples, the heat absorption began at the melting point.

In the heating experiment G1 on the first sample, heat absorption continued up to about 45° C. In contrast, in the heating experiment G4 on the fourth sample, the heat absorption continued up to about 40° C. This shows that as the pore density of the substrate 110 of the composite structure 100 increases, it takes longer for the phase-change layer 130 to complete the phase change from solid to liquid. The greater the pore density of the substrate 110 of the composite structure 100, the greater the occupying arear of the interface layer 120. As the occupying area of the interface layer 120 increased, the thermal conductivity of the composite structure 100 decreased, and the time required for the phase change lengthened.

According to an embodiment of the present inventive concept, a composite structure may include a phase-change layer having a phase that can be changed from solid to liquid at room temperature. Thus, the phase-change layer may absorb heat nearly the same, and in this embodiment, the phase-change layer may reduce a heating issue in an electronic device with the composite structure.

According to an embodiment of the present inventive concept, a composite structure may include an interface layer, which can be used to expedite the nucleation process in the phase change process of the phase-change layer, and thus, the phase of the phase-change layer may be changed from liquid to solid at the room temperature. Accordingly, a supercooling issue may be alleviated. Accordingly, the phase-change layer may be restored to the solid phase at the room temperature.

While non-limiting embodiments of the present inventive concept have been particularly shown and described, it will be understood by one of ordinary skill in the art that variations in form and detail may be made therein without departing from the spirit and scope of the present inventive concept.

What is claimed is:

1. A composite structure, comprising:
a substrate including at least one void;
a phase-change layer filling at least a portion of the at least one void; and
an interface layer between the substrate and the phase-change layer,
wherein the substrate comprises copper (Cu),
the phase-change layer comprises gallium (Ga),
the interface layer comprises a copper gallium (CuGa₂) compound, and
the interface layer is in direct contact with the substrate and the phase-change layer.

2. The composite structure of claim 1, wherein the interface layer fills at least a portion of the at least one void.

3. The composite structure of claim 1, wherein a pore density of the substrate is greater than or equal to about 50 pore per inch.

4. The composite structure of claim 3, wherein the pore density of the substrate is less than or equal to about 80 pore per inch.

5. The composite structure of claim 1, wherein the phase-change layer comprises a first portion in the at least one void and a second portion that is spaced apart from an outside of the at least one void.

6. The composite structure of claim 5, wherein a thickness of the interface layer is less than a width of the first portion of the phase-change layer.

7. The composite structure of claim 5, wherein the interface layer comprises:
a first layer in direct contact with the first portion of the phase-change layer; and
a second layer in direct contact with the second portion of the phase-change layer.

8. The composite structure of claim 7, wherein an entirety of the at least one void of the substrate is filled with the first layer of the interface layer and the first portion of the phase-change layer.

9. The composite structure of claim 7, wherein:
the substrate comprises an inner surface in direct contact with the first layer of the interface layer and an outer surface in direct contact with the second layer of the interface layer;
the inner surface of the substrate and the first portion of the phase-change layer are spaced apart from each other with the first layer of the interface layer interposed therebetween; and
the outer surface of the substrate and the second portion of the phase-change layer are spaced apart from each other with the second layer of the interface layer interposed therebetween.

10. The composite structure of claim 7, wherein the second portion of the phase-change layer fully covers the second layer of the interface layer.

11. A composite structure, comprising:
a substrate including at least one void;
a phase-change layer filling at least a portion of the at least one void; and
an interface layer between the substrate and the phase-change layer,
wherein the substrate comprises copper (Cu),
the phase-change layer comprises gallium (Ga),
the interface layer comprises a copper gallium (CuGa₂) compound,
the interface layer comprises a first layer disposed in the at least one void and a second layer disposed outside of the at least one void, and
the substrate is disposed between the first layer and the second layer.

12. The composite structure of claim 11, wherein a nucleation process of the phase-change layer begins on a surface in direct contact with the interface layer, when a phase of the phase-change layer is changed from liquid to solid.

13. The composite structure of claim 11, wherein:
a grain of the interface layer comprises a first side, a second side, and a third side that are connected to each other,
the first to third sides cross each other; and
the grain of the interface layer has a cuboidal shape, wherein a length of the third side is greater than a length of the first side and a length of the second side.

14. The composite structure of claim 11, wherein:
the phase-change layer comprises a first portion in direct contact with the first layer of the interface layer and a second portion in direct contact with the second layer; and
the substrate and the interface layer are disposed between the first portion and the second portion.

15. The composite structure of claim 11, wherein when a phase of the phase-change layer is changed from liquid to solid, a nucleation process begins between about 5° C. and about 29.8° C.

16. A composite structure, comprising:
a substrate including at least one void;
a phase-change layer filling at least a portion of the at least one void; and
an interface layer in direct contact with the substrate and the phase-change layer,
wherein the substrate comprises copper (Cu),
the phase-change layer comprises gallium (Ga),
the interface layer comprises a copper gallium (CuGa₂) compound, and
the substrate is spaced apart from the phase-change layer by the interface layer.

17. The composite structure of claim 16, wherein an entirety of the at least one void is filled with the phase-change layer and the interface layer.

18. The composite structure of claim 16, wherein the interface layer encloses an entire surface of the substrate.

19. The composite structure of claim 16, wherein the phase-change layer surrounds an entire surface of the interface layer.

20. The composite structure of claim 16, wherein the substrate is closed by the phase-change layer and the interface layer.
